(19) United States
(12) Patent Application Publication
(10) Pub. No.: US 2015/0257280 A1
(43) Pub. Date: Sep. 10, 2015

(54) METHOD FOR PRODUCING A DRIED PASTE LAYER, METHOD FOR PRODUCING A SINTERING CONNECTION, METHOD FOR PRODUCING A POWER SEMICONDUCTOR MODULE AND CONTINUOUS INSTALLATION

(71) Applicant: Infineon Technologies AG, Neubiberg (DE)

(72) Inventors: Alexander Ciliox, Moehnesee (DE); Nicolas Heuck, Cremlingen (DE); Christian Stahlhut, Rinteln (DE)

(21) Appl. No.: 14/639,635

(22) Filed: Mar. 5, 2015

(30) Foreign Application Priority Data
Mar. 6, 2014 (DE) 102014103013.3

(51) Int. Cl. H05K 3/34; B23K 35/02; B23K 1/00; B23K 31/02; B05D 3/02; B05D 5/00

(52) U.S. Cl. CPC H05K 3/3484; B05D 3/0254; B05D 5/00; B23K 1/0016; B23K 31/02; B23K 35/025; H05K 3/341; H05K 2203/04

(57) ABSTRACT

One aspect of the invention relates to producing a dried paste layer on a joining partner. For this purpose, a joining partner having a contact surface is provided, to which contact surface a paste is applied. Furthermore, a heating device is provided, which is preheated to a preheating temperature. The paste applied to the contact surface is then dried during a drying phase, such that a dried paste layer arises from the paste. In the drying phase, the joining partner and the preheated heating device are at a distance of at most 5 mm.

### PRIORITY CLAIM

This application claims priority to German Patent Application No. 10 2014 103 013.3 filed on 6 Mar. 2014, the content said application incorporated herein by reference in its entirety.

### BACKGROUND

In order to produce joining connections it is known to introduce sinterable paste between the joining partners and to sinter the paste, thereby giving rise to a fixed sintering connection. This technology is used, inter alia, in power semiconductor modules for joining connections which are subjected to an intensive loading caused by thermal cycling during operation of the power semiconductor module. Compared with conventional joining connections such as soldering or adhesive-bonding connections, for example, sintering connections exhibit a significantly better long-term stability.

Before the actual sintering process, a spreadable paste comprising sinterable particles and a solvent is applied to at least one of the joining partners and then dried. During drying, which usually takes place in a drying chamber, a large part of the solvent is removed, such that a dried paste layer remains behind. Only the dried paste layer is then sintered. This method is very time-consuming, however, since the drying chambers must first be loaded and be emptied again after drying. Moreover, heating up takes a great deal of time.

### SUMMARY

The object of the present invention is to provide methods by which sintering connections can be produced more rapidly than heretofore and an installation for realizing said methods. These objects are achieved by means of a method for producing a dry paste layer as claimed in patent claim 1, by means of a method for producing a sintering connection between a first joining partner and a second joining partner as claimed in patent claim 17 and respectively by means of a continuous installation as claimed in patent claim 22. Dependent claims relate to configurations and developments of the invention.

In order to produce a dried paste layer on a (first) joining partner, a (first) joining partner having a contact surface is provided, to which contact surface a paste is applied. Furthermore, a heating device is provided, which is preheated to a preheating temperature. The paste applied to the contact surface is then dried during a drying phase, such that a dried paste layer arises from the paste. In the drying phase, the (first) joining partner and the preheated heating device are at a distance of at most 5 mm, this being inclusive of a distance of 0 mm. In the case of a distance of 0 mm, the (first) joining partner and the heating device touch one another.

With the aid of this drying method, it is possible to produce a sintering connection between the first joining partner and a second joining partner. For this purpose—following the above-described method for producing a dry paste layer—the first joining partner and the second joining partner are arranged relative to one another in such a way that the dried paste layer is situated between the first joining partner and the second joining partner. The dry paste layer is subsequently sintered during a sintering phase. During the sintering phase, the first joining partner and the second joining partner and also the dried paste layer situated between them remain pressed against one another uninterruptedly under the action of a press-on pressure. During the sintering phase, therefore, the dried paste layer is uninterruptedly arranged between the first joining partner and the second joining partner and contacts then.

The drying method outlined above can be realized for example by means of a continuous installation designed to produce a respective dried paste layer sequentially on a multiplicity of joining partners in accordance with the drying method outlined.

### BRIEF DESCRIPTION OF THE DRAWINGS

The invention is explained in greater detail below on the basis of exemplary embodiments with reference to the accompanying figures. In the figures, identical reference signs designate identical or identically acting elements. In the figures:

FIGS. 1A to 1N show various steps of a method for producing a sintering connection between two joining partners;

FIG. 2 shows the production of a sintering connection between two joining partners in a continuous method;

FIG. 3 shows two joining partners, whose contact surfaces to be connected to one another by means of a sintering connection are formed in each case by a noble metal surface;

FIG. 4 shows one exemplary embodiment for producing a sintering connection between a ceramic substrate and a semiconductor chip;

FIG. 5 shows one exemplary embodiment for producing a sintering connection between a baseplate for a power semiconductor module and a ceramic substrate;

FIG. 6 shows one exemplary embodiment for heating a joining partner by means of a heating device having a plurality of pressing stamps;

FIG. 7 shows one exemplary embodiment for cooling a joining partner by means of a cooling device having a plurality of pressing stamps;

FIGS. 8A and 8B show the heating of a joining partner, in the course of which an elastic and thermally conductive pressure element is arranged between the heating device and the joining partner;

FIG. 9 shows the cooling of a joining partner, in the course of which an elastic and thermally conductive pressure element is arranged between the cooling device and the joining partner;

FIG. 10 shows one exemplary embodiment for heating a joining partner by means of a heating device spaced apart from the joining partner;

FIG. 11A shows the production of a sintering connection between a first joining partner and a second joining partner in a continuous installation, in which a transport carrier is used for transporting the first joining partner provided with the paste;

FIG. 11B shows an enlarged sectional view of the continuous installation in accordance with FIG. 11A in a sectional plan E1-E1;

FIG. 11C shows an enlarged sectional view of the continuous installation in accordance with FIG. 11A in a sectional plane E2-E2; and

FIG. 12 shows an alternative to FIG. 11C, this alternative corresponding to FIG. 10, in which the heating device, during the drying phase, is permanently or temporarily spaced apart from the first joining partner 1 inserted into a transport carrier.

### DETAILED DESCRIPTION

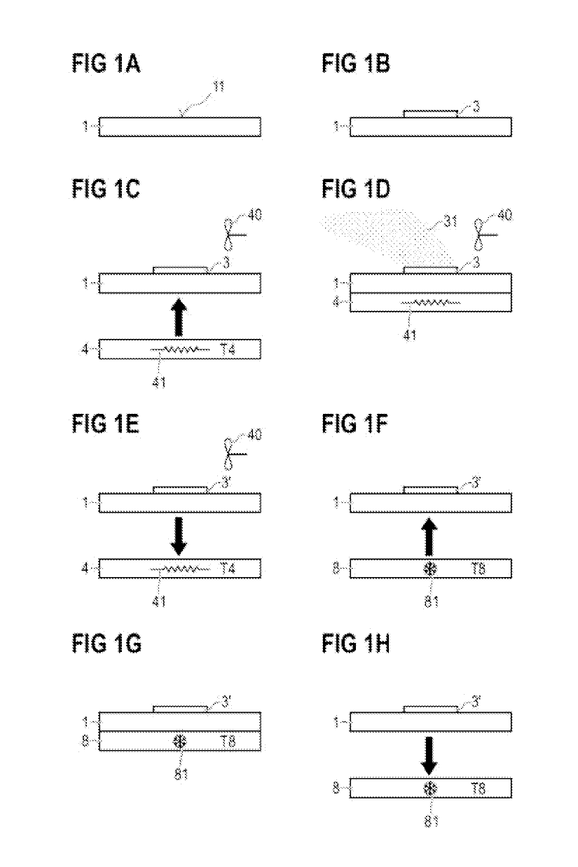

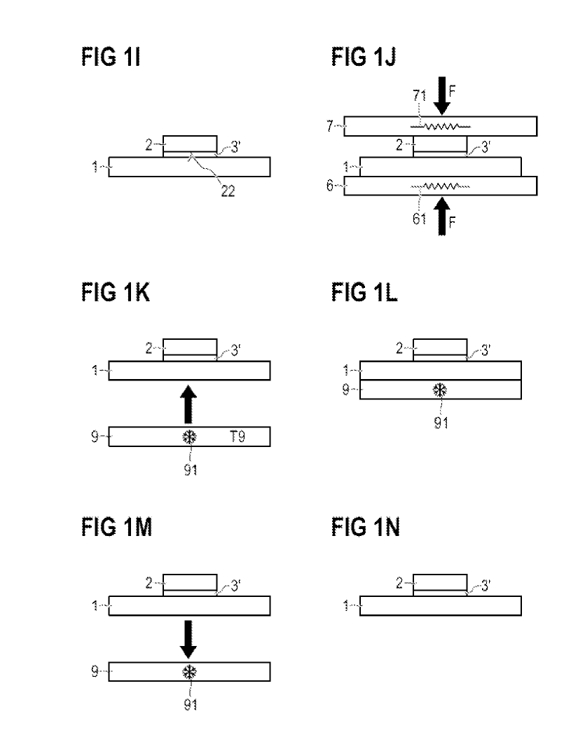

FIG. 1A shows a first joining partner 1. The latter has a first contact surface 11, to which, as is shown as the result in FIG. 1B, a paste 3 is applied. Application can be carried out for example in a stencil or screen printing method, or by dispensing. The paste 3 contains a metal powder and a solvent. Optionally, the powder particles can also be embodied as flat flakes. After application to the first joining partner 1, the paste 3 can have a layer thickness d3 of at least 5 μm, for example. However, smaller or larger layer thicknesses d3 are likewise possible.

Suitable metals for the metal powder include noble metals such as silver, gold, platinum, palladium, rhodium, for example, but also non-noble metals such as copper, for example. The metal powder of the paste can completely consist of one of the metals mentioned or comprise one of said metals; however, it can also consist of metal powder mixtures comprising two or more of the metals mentioned or comprise such a metal powder mixture.

Silver is preferably used as metal since the sintered layer produced therefrom has an excellent electrical and also thermal conductivity, which is of importance primarily in the field of power electronics, for example if, via the sintering connection layer, power semiconductor chips are intended to be mounted on a carrier and in the process electrically conductively connected to the carrier and/or subjected to heat dissipation via the latter.

In order then to dry the paste 3 applied to the contact surface 11 of the first joining partner 1, at least a considerable proportion of the solvent must be removed from the paste 3. For this purpose, the invention provides for using a heating device 4, which is preheated (see FIG. 1C) to a preheating temperature T4, for example at least 50° C. or at least 120° C., and is then used to heat the first joining partner 1 with the paste 3 situated thereon during a drying phase. For this purpose, the first joining partner 1 and the preheated heating device 4 can be kept in a distance range that is not greater than a maximum distance, for example 5 mm or 0.5 mm, during the entire drying phase. This includes a distance equal to zero, at which there is a direct contact between the heating device 4 and the first joining partner. The heating device 4 and the first joining partner 1 can therefore contact one another uninterruptedly during the entire drying phase, or they can be kept in a distance range that is greater than or equal to zero, but less than or equal to the maximum distance, during the entire drying phase or they can be kept in a distance range that is greater than zero, but less than the maximum distance, during the entire drying phase.

On account of the small maximum distance, the first joining partner 1 and the paste 3 applied thereto are heated by the heat emitted by the heating device 4, such that the solvent 31 escapes from the paste 3 (see FIG. 1D). The duration of the drying phase can be for example at least 1 second, at least 30 seconds or at least 60 seconds.

In order to prevent the temperature of the heating device 4 from decreasing to an excessively greater extent after the beginning of the drying phase, the heating device 4 can optionally have an absolute heat capacity that is at least 10 times the absolute heat capacity of the first joining partner 1.

The evaporating solvent 31 and reaction products possibly brought about thereby can be captured by means of a local extraction by suction. The extraction by suction can be supported by e.g. gas nozzles or a fan 40 by which the evaporating solvent 31 and, if appropriate, the reaction products are extracted by suction or the evaporating solvent 31 and, if appropriate, the reaction products that arise have impressed on them a target direction in which they are blown away from the first joining partner 1.

Subsequent rapid cooling of the heated first joining partner 1, in the course of which the latter is cooled with a steeply falling slope, can be achieved by means of compressed air (or protective gases such as e.g. nitrogen) or via a second permanently cooled body (e.g. a cooling block).

At the point in time at which the thermal contact between the preheated heating device 4 and the joining partner 1 is produced, the paste 3 applied to the first joining partner 1 can have a metal proportion of 50 percent by mass to 90 percent by mass, for example. Smaller or larger metal proportions are likewise possible, however.

In order to end the drying phase, the distance between the heating device 4 and the joining partner 1 is increased again, which is illustrated as the result in FIG. 1E. A dry paste layer 3′ then remains as residue of the paste 3 on the contact surface 11. Said dry paste layer can have a metal proportion of at least 95 percent by mass, for example.

During the drying phase, very fast heating of the paste 3 in comparison with conventional drying methods and in association with this a very fast drying process occur on account of the good thermal coupling.

In a corresponding manner, it is optionally likewise possible to cool the first joining partner 1 with the dry paste layer 3′ situated thereon by means of a cooling device 8. This makes it possible, as necessary, to prevent the paste layer 3′ from drying out to an excessively great extent.

For cooling purposes, firstly, as shown in FIG. 1F, a cooling element 8 is provided, which is precooled to a cooling temperature T8 and which then, as illustrated in FIG. 1G, is brought into thermal contact with the first joining partner 1 or to thermal proximity (maximum distance with one of the values mentioned for the drying phase) to said first joining partner during a cooling phase, such that the first joining partner 1 and the dry paste layer 3′ situated on the contact surface 11 of said first joining partner are cooled. Optionally, in this case, the thermal contact or the thermal proximity between the precooled cooling device 8 and the joining partner 1 can take place at that side of the first joining partner 1 which faces away from the dry paste layer 3′. In order to end the cooling phase, the distance between the cooling device 8 and the joining partner 1 is increased, which is illustrated in FIG. 1H.

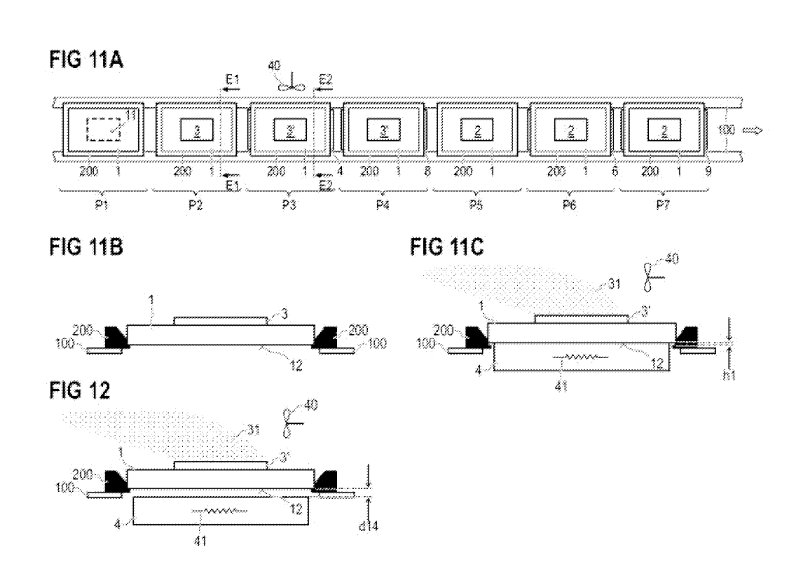

After the production of the dry paste layer 3′, if appropriate after the optional cooling phase, a second joining partner 2 can be cohesively connected to the first joining partner 1 provided with the dried paste layer 3′, by means of the first joining partner 1 and the second joining partner 2 being arranged relative to one another such that the dried paste layer 3′ is situated between the first joining partner 1 and the second joining partner 2 and in this case contacts each of the joining partners 1 and 2. By way of example, for this purpose, the second joining partner 2 can be placed onto that side of the dried paste layer 3′ which faces away from the first joining partner 1, as is illustrated as the result in FIG. 11.

During a sintering phase, during which the first joining partner 1 and the second joining partner 2 remain pressed against one another uninterruptedly under the action of a press-on pressure, such that the dried paste layer 3′ remains arranged between the first joining partner 1 and the second joining partner 2 and uninterruptedly contacts both joining partners 1, 2, the dried paste layer 3′ is sintered.

In this case, the press-on pressure can be kept permanently in a pressure range of at least 5 MPa during the entire sintering phase. Moreover, at least the dry paste layer 3′ can be kept permanently in a temperature range of not less than 200° C. during the sintering phase. Furthermore, at least the dried paste layer 3′ can be kept permanently in a temperature range of not more than 350° C. during the sintering phase. In comparison with conventional sintering temperatures, these temperatures are relatively low, which is advantageous primarily if at least one of the joining partners 1, 2 is a temperature-sensitive component such as a semiconductor component, for example. In principle, however, the sintering temperatures can also be chosen to be less than 200° C. or greater than 350° C.

FIG. 1J shows the sintering process, in the course of which the arrangement with the dry paste layer 3′ situated between the joining partners 1, 2 is clamped in between two heated stamps 6, 7, each having a stamp heating system 61 and 62, respectively. Optionally, it is also possible for only one of the two stamps 61, 62 to be heated. The result at all events is a composite in which the two joining partners 1 and 2 are cohesively connected to one another by the sintered dried paste layer 3′.

After the conclusion of the sintering process, said composite 1, 2, 3′ can be cooled, once again optionally. For this purpose, as is shown in FIG. 1K, a further cooling element 9 is provided, which is precooled to a cooling temperature T9 and which then, as illustrated in FIG. 1L, is brought into thermal contact with the first joining partner 1, such that the composite 1, 2, 3′ is cooled. Optionally, in this case, the thermal contact between the precooled cooling device 9 and the joining partner 1 can be carried out at this side of the first joining partner 1 which faces away from the dry paste layer 3′. In order to end the cooling phase, the thermal contact between the cooling device 9 and the joining partner 1 is released again, which is illustrated in FIG. 1M. FIG. 1N, finally, shows the finished composite 1, 2, 3′.

By means of the time-controlled thermal coupling and decoupling or approach and removal of the heating element 4 and (if provided) of the cooling elements 8 and/or 9, a temperature profile having very steep temperature slopes can be obtained for the first joining partner 1 and the paste 3 applied thereto.

Optionally—independently of one another—the temperatures T4 in the heating phase and (if the use of cooling elements 8 and/or 9 is provided) T8 and T9 in the relevant cooling phase can also be controlled by closed-loop control in each case.

The heating system 41 of the heating device 4 can be embodied for example as electrical heating coils. The cooling system 81 and 91 of the cooling device 8 and 9, respectively, can be implemented for example with the aid of a cooling liquid passed through the relevant cooling device 8, 9. In principle, however, the heating of a heating device 4 and respectively the cooling of a cooling device 8, 9 can be implemented by any other methods desired.

In principle, it is not necessary for the sintering process to be carried out directly after the paste 3 has been applied to the first joining partner 1 and dried. It is likewise possible to carry out the sintering process at a later point in time. The drying process then ends with the end of the drying phase (FIG. 1E) or, if a subsequent cooling step is provided, with the end of the cooling phase effected by the cooling device 8.

A further advantage of the method outlined is that no drying chamber is required for drying the paste. As a result, at least the drying process and optionally also a subsequent sintering process can be carried out in a simple manner in a continuous method (in line process) in which many, for example identical, joining partners 1 are provided with a paste 3 and the latter is then dried as described. If a sintering process is also provided in the continuous method, a respective second joining partner 2 can also be cohesively connected to a respective first joining partner 1, on which a dried paste layer 3′ was produced beforehand, by sintering. Optionally, the application of the paste 3 to the first joining partners 1 can also be carried out in the context of the continuous method.

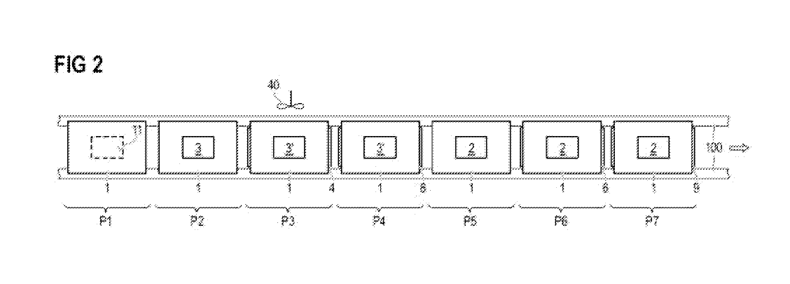

FIG. 2 shows one example of a continuous installation for carrying out a continuous process. The illustration shows various first joining partners 1 in each case in a different process stage P1 to P7 such as have already been explained with reference to FIGS. 1A to 1H. In order to realize the continuous process, a conveying device 100 is used, which transports the first joining partners 1, in the further course also the unit comprising the first joining partner 1 and the paste 3 applied thereto, and later in addition the second joining partner 2 as well, from one process stage into a subsequent process stage. The conveying device 100 is embodied as a conveyor belt merely by way of example in FIG. 2. In principle, however, the configuration of the conveying device 100 can be chosen in any manner desired. In this regard, for example, gripping devices, suction-lifting apparatuses, etc. can also be used.

Process stage P1 exhibits—corresponding to FIG. 1A—a first joining partner 1 having a contact surface 11. In process stage P2, as explained with reference to FIG. 1B, a paste 3 is applied to the contact surface 11. In process stage P3, the drying process is carried out, as explained with reference to FIGS. 1C to 1E. The optional process stage P4 represents a cooling process, explained with reference to FIGS. 1F to 1H. In process stage P5, a second joining partner 2 is brought into contact with the dry paste layer 3′ applied to the first joining partner 1, as has already been explained with reference to FIG. 11, and in process stage P6, as explained with reference to FIG. 1J, said second joining partner is cohesively connected to the first joining partner 1 by the sintering of the dry paste layer 3′. For reasons of clarity, the illustration of the press stamp 7 has been dispensed with in process stage P6. The optional process stage P7, finally, represents an optional cooling process, explained with reference to FIGS. 1K to 1N.

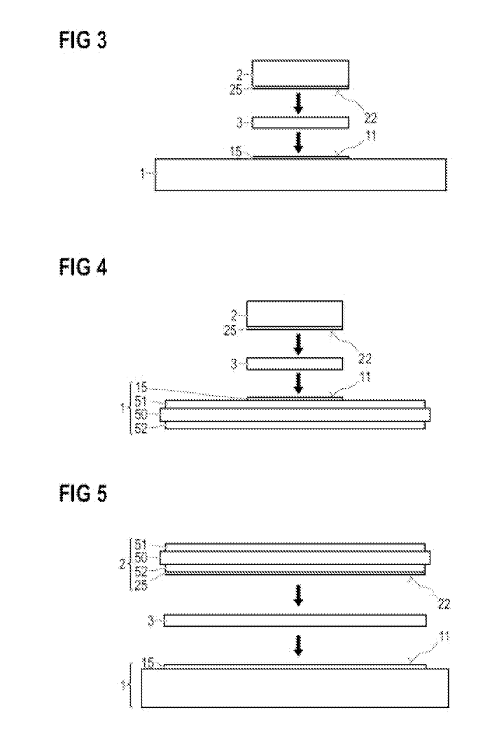

In order to obtain sintered cohesive connections of particularly high quality, it is advantageous if the contact surface 11 of the first joining partner 1, to which contact surface the paste 3 is applied, and also a contact surface 22 of the second joining partner 2, which contact surface is brought into contact with the dried paste layer 3′, are formed in each case by a noble metal. For this purpose, as shown schematically in FIG. 3, the first joining partner 1 can be provided with a noble metal layer 15 and/or the second joining partner can be provided with a noble metal layer 25. Examples of suitable noble metals for producing these layers include silver, gold, platinum, palladium, rhodium or alloys comprising or consisting of two or more of the metals mentioned. The paste 3 is merely illustrated schematically in order to clarify its later position which it assumes later as a dry paste layer 3′.

FIGS. 4 and 5 also show concrete examples of arrangements corresponding to FIG. 3. In FIG. 4, the first joining partner 1 is embodied as an electronic circuit carrier having an electrically insulating ceramic layer 50, which is provided with an upper metallization layer 51 and with an optional lower metallization layer 52. The ceramic layer 50 can consist of silicon nitride, aluminum oxide, zirconium oxide or silicon carbide, for example. The metallization layers 51, 52 can consist e.g. of copper, a copper alloy, aluminum or an aluminum alloy. However, other metals can likewise be used. In particular, the circuit carrier can be a DCB substrate (ceramic layer 50 composed of aluminum oxide and metallization layers 51 and, if appropriate 52 composed of copper or a copper alloy having a high proportion of copper), or a DAB substrate (DAB=direct aluminum bonding; aluminum metallization 51 and, if appropriate, 52 is directly connected to ceramic layer 50) or an AMB substrate (AMB=active metal brazing; metallization layers 51 and, if appropriate, 52 are connected to ceramic layer 50 by active brazing). Alternatively, the circuit carrier could also be an IMS substrate (IMS=insulated metal substrate; a metal substrate is firstly provided with a dielectric layer, to which a metal layer is applied, which is electrically insulated from the metal substrate by the dielectric layer; the metal layer then corresponds to the upper metallization layer 51).

The second joining partner 2 is a semiconductor chip, for example a diode, an IGBT, a MOSFET or any other semiconductor component. By means of the sintered connection between the semiconductor chip and the circuit carrier, the semiconductor chip can be electrically connected to the upper metallization layer 51 and/or be subjected to heat dissipation via the circuit carrier.

In FIG. 5, the first joining partner 1 is a baseplate for a power semiconductor module. The second joining partner 2 comprises a substrate with a ceramic layer 50, an upper metallization layer 51 and with an optional lower metallization layer 52, as already explained with reference to FIG. 4, or an IMS substrate, likewise explained with reference to FIG. 4. While the optional noble metal layer 15 is applied to the upper metallization layer 51 in the case of the circuit carrier 1 in accordance with FIG. 4, the noble metal layer 25 is applied to the lower metallization layer 52 in the case of the circuit carrier in accordance with FIG. 5.

The baseplate can be a metal plate, which can consist of copper or a copper alloy, for example, or of a metal matrix composite material (MMC), and which can optionally be provided with a noble metal layer 25. In the case of the arrangement in accordance with FIG. 5, the second joining partner 2 could optionally already be previously equipped with one or a plurality of semiconductor chips at its upper metallization layer 51. By way of example, the second joining partner 2 could be embodied as a composite such as is present after the production of the sintered connection between the joining partners 1, 2 explained with reference to FIG. 4. The noble metal layer 25 illustrated in FIG. 5 could be applied to the lower metallization layer 52 before or after the production of the sintered connection.

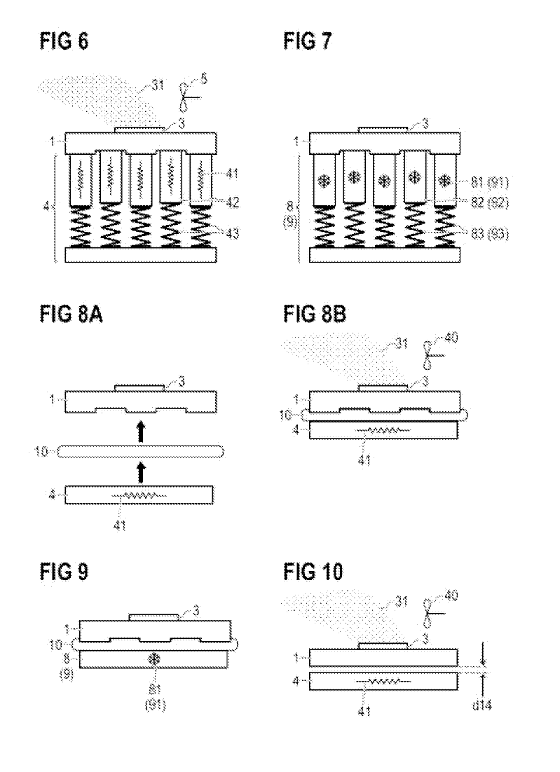

While the heating device 4 explained previously was embodied as a solid block, for example as a single, heatable metal block, FIG. 6 shows another alternative configuration, in which the heating device 4 has a plurality of heatable pressing stamps 42. In this case, the heat capacity of the heating device 4 consists of the sum of the heat capacities of the pressing stamps 42. The pressing stamps 42 are pressed against the first joining partner 1 in each case by means of a spring device 43. As a result, a good thermal coupling between the heating device 4 and the first joining partner 1 and thus rapid heating of the first joining partner 1 and of the paste 3 applied thereto can be ensured even if that side of the first joining partner 1 with which the heating device 4 is brought into thermal contact is irregular and/or bends upon heating on account of different coefficients of thermal expansion of the materials involved.

A corresponding construction can also be used for the cooling devices 8, 9 explained. While the cooling devices 8, 9 explained previously were embodied in each case as a solid block, for example as a single, cooled metal block, FIG. 7 shows another alternative configuration, in which the cooling devices 8 and/or 9 have a plurality of cooled pressing stamps 82 and/or 92, respectively. The pressing stamps 82 and/or 92 are pressed against the first joining partner 1 in each case by means of a spring device 83 and/or 93, respectively. As a result, a good thermal coupling between the cooling device 8 and/or 9 and the first joining partner 1 and thus rapid dissipation of heat from the first joining partner 1 and the dried paste layer 3 arranged thereon or from the composite comprising the joining partners 1, 2 and the dried and sintered paste layer 3′ can be ensured even if that side of the first joining partner 1 with which the cooling device 8 and/or 9 is brought into thermal contact is irregular and/or bends in the event of a change in temperature on account of different coefficients of thermal expansion of the materials involved.

A further measure for producing a good thermal contact between an uneven thermal contact surface of a first joining partner 1 and a heating device 4 or a cooling device 8 or 9 is shown for a heating device 4 in FIGS. 8A and 8B and for a cooling device 8 and/or 9 in FIG. 9. In all cases, an elastic and thermally conductive pressure element 10 is arranged between the heating device 4 or the cooling device 8 or 9, on the one hand, and the thermal contact surface of the first joining partner 1, on the other hand. When the heating device 4 or one of the cooling devices 8 or 9 is pressed against the first joining partner 1, the pressure element adapts to the uneven thermal contact surface and provides for a good thermal coupling between the first joining partner, on the one hand, and the heating device 4 or the cooling device 8 or 9, on the other hand. Examples of suitable pressure elements 10 included a knitted metal fabric and/or a metal nonwoven and/or a metal sponge.

Independently of the construction of a heating device 4 or of a cooling device 8, 9, they can be embodied—independently of one another—for example as a simple block, as a round body or as a tube. In principle, however, arbitrary geometrical shapes can be used. Owing to the high thermal conductivity, metals, for example, also including nonferrous metals, are suitable as materials for the heating device 4 or the cooling devices 8, 9.

If desired, the decomposition of the solvent 31 during the drying phase (FIG. 1D) and/or the arising or decomposition of reaction products that possibly arise during the drying phase can be controlled by the targeted setting and monitoring of an atmosphere if the drying phase is carried out in a completely or at least predominantly closed process chamber. By way of example, in such a process chamber, by means of a defined addition of oxygen, for example, a presintering process can be instigated in order to initiate or accelerate consolidation of the applied paste 3. Alternatively, an atmosphere present in the process chamber and comprising inert, passive gases (“protective gases”) such as nitrogen, argon, for example, prevents the paste 3 and possibly constituents of the first joining partner 1 from reacting with constituents of the ambient air. In this regard, it can be advantageous, for example, to prevent the oxidation of copper metallizations 51, 52 of a substrate or of a semiconductor chip or of a copper-containing baseplate of a power semiconductor module in order not to hamper joining processes performed later on these copper-containing constituents, such as e.g. soldering or wire bonding processes.

While FIGS. 1D and 6 illustrate heating phases during which the heating device 4 permanently contacts the first joining partner 1, FIG. 10 shows an example in which a distance d14 is permanently maintained between the heating device 4 and the first joining partner 1 during the heating phase, said distance not being greater than a maximum distance of 5 mm or 0.5 mm.

FIG. 11A shows a continuous installation like FIG. 2. A continuous process is carried out therein, and this continuous process differs from the continuous process shown in FIG. 2 by virtue of the fact that the conveying device 100 conveys the first joining partner 1 on a transport carrier 200 through the installation. For this purpose, the transport carrier 200 can bear on the conveying device 100, for example a conveyor belt or some other conveying device. As already shown in FIG. 2, a conveyor belt can be embodied in two parts and have two partial conveyor belts running parallel to one another, on which the transport carrier 200 (only the first joining partner 1 in FIG. 2) is placed.

As evident from the enlarged sectional view in accordance with FIG. 11B in conjunction with FIG. 11A, the transport carrier 200 can be embodied such that the underside 12 of the first joining partner 1, said underside being opposite to the first contact surface 11, is freely accessible. This affords the possibility of the underside 1b being sufficiently approached or contacted by a heating device 4 or a cooling device 8, 9. In particular, the transport carrier 200 can be configured such that it is possible to maintain the abovementioned maximum distance of 5 mm or even just 0.5 mm.

While FIG. 11B shows the arrangement before the drying phase, FIG. 11C illustrates the drying phase. Optionally, the first joining partner 1 can be lifted off from the transport carrier 200 by the heating device 4 by a distance h1, for example at least 0.1 mm, in order to thermally decouple the first joining partner 1 from the transport carrier 200 and thereby prevent heat from being dissipated from said first joining partner by the transport carrier 200. The lift-off can be carried out for example by the heating device 4, as shown in FIGS. 10 and 1D, being moved toward the first joining partner 1 from below. Alternatively, there is also the possibility that the first joining partner 1, during its transport by the conveying device in the conveying direction, is pushed onto the heating device 4 and raised by the distance h1 in the process. In order to facilitate sliding of the first joining partner 1 onto the heating device 4, the heating device 4 can have a ramp, for example.

As has been shown with reference to FIGS. 2 and 11A, the application of the paste 3 to the first joining partner 1 can be carried out at a point in time at which the first joining partner 1 (as directly in FIG. 2 or as indirectly on the transport carrier 200 in FIG. 11A) bears on the conveying device 100. However, it is likewise possible for a first joining partner 1 firstly to be provided with the paste 3 and only then to be placed onto the conveying device 100 directly or indirectly.

FIG. 12 also shows an alternative to FIG. 11C, this alternative corresponding to FIG. 10, in which the heating device 4, during the drying phase, is permanently or temporarily spaced apart from the first joining partner 1 inserted into a transport carrier 200.

What is claimed is:

1. A method for producing a dried paste layer on a joining partner comprising the following steps:
providing a joining partner having a contact surface, to which a paste is applied;
providing a heating device, which is preheated to a preheating temperature;
drying the paste applied to the contact surface during a drying phase, in which the preheated heating device and the joining partner are at a distance of at most 5 mm, such that a dried paste layer arises from the paste.

2. The method as claimed in claim 1, wherein the heating device and the joining partner are brought into direct thermal contact during the drying phase.

3. The method as claimed in claim 1, wherein there is a direct thermal contact between the heating device and the joining partner during the entire drying phase.

4. The method as claimed in claim 1, wherein the joining partner with the paste applied to its contact surface is placed onto a transport carrier before the beginning of the drying phase.

5. The method as claimed in claim 4, wherein the joining partner is lifted off from the transport carrier in the drying phase.

6. The method as claimed in claim 1, wherein the joining partner together with the paste applied to its contact surface is conveyed to the heating device by means of a conveyor belt before the drying phase.

7. The method as claimed in claim 1, comprising the following further steps:
providing a precooled cooling device, which is precooled to a precooling temperature that is lower than the preheating temperature;
producing a thermal contact between the precooled cooling device and the joining partner with the dried paste layer situated thereon.

8. The method as claimed in claim 1, wherein the paste has a metal proportion of 50 percent by mass to 90 percent by mass at the beginning of the drying phase.

9. The method as claimed in claim 1, wherein the paste is applied to the joining partner as a layer having a thickness of greater than or equal to 5 μm.

10. The method as claimed in claim 1, wherein the preheating temperature is at least 50° C. or at least 120° C.

11. The method as claimed in claim 1, wherein the heating device has an absolute heat capacity that is at least 10 times the absolute heat capacity of the joining partner.

12. The method as claimed in claim 1, wherein the drying phase is maintained for a duration of at least 1 second or of at least 30 seconds or of at least 60 seconds.

13. The method as claimed in claim 1, wherein the dried paste layer has a metal proportion of at least 95 percent by mass after the drying phase.

14. The method as claimed in claim 1, wherein the contact surface is formed by a noble metal layer.

15. The method as claimed in claim 14, wherein the noble metal layer comprises at least one of: silver, gold, platinum, palladium, rhodium.

16. The method as claimed in claim 1, wherein the joining partner is embodied
as a baseplate for a power semiconductor module, or
as an electronic circuit carrier having an electrically insulating ceramic layer, to which a metallization layer is applied.

17. A method for producing a sintering connection between a first joining partner and a second joining partner comprising the following steps:
producing a dried paste layer on a first joining partner according to the method as claimed in claim 1;
providing a second joining partner;
arranging the first joining partner and the second joining partner relative to one another in such a way that the dried paste layer is arranged between the first joining partner and the second joining partner; and
subsequently
sintering the dried paste layer during a sintering phase during which
the first joining partner and the second joining partner remain pressed against one another uninterruptedly under action of a press-on pressure;
the dried paste layer is arranged between the first joining partner and the second joining partner and uninterruptedly contacts each of them.

18. The method as claimed in claim 17, wherein the press-on pressure during the sintering phase does not fall below a pressure of 5 MPa.

19. The method as claimed in claim 17, wherein the dried paste layer is kept permanently in a temperature range of not less than 200° C. during the sintering phase.

20. The method as claimed in claim 17, wherein the dried paste layer is kept permanently in a temperature range of not more than 350° C. during the sintering phase.

21. The method as claimed in claim 17, wherein
the first joining partner is embodied as a baseplate for a power semiconductor module, and the second joining partner is embodied as an electronic circuit carrier having an electrically insulating ceramic layer to which a metallization layer is applied; or
the first joining partner is embodied as an electronic circuit carrier having an electrically insulating ceramic layer, to which a metallization layer is applied, and the second joining partner is embodied as a semiconductor chip.

22. A continuous installation designed to produce, in a continuous method, a respective dried paste layer successively on a multiplicity of joining partners according to the method as claimed in claims 1.
